(19) United States
(12) Patent Application Publication
(10) Pub. No.: US 2024/0110284 A1
(43) Pub. Date: Apr. 4, 2024

(54) Selective Deposition of Thin Films with Improved Stability

(71) Applicant: Applied Materials, Inc., Santa Clara, CA (US)

(72) Inventors: Lulu XIONG, Singapore (SG); Kevin Hsiao, Hsinchu (TW); Chris LIU, Hsinchu (TW); Chieh-Wen LO, Hsinchu (TW); Sean M. SEUTTER, San Jose, CA (US); Deenesh PADHI, Santa Clara, CA (US); Prayudi LIANTO, Singapore (SG); Peng SUO, Singapore (SG); Guan Huei SEE, Singapore (SG); Zongbin WANG, Singapore (SG); Shengwei ZENG, Singapore (SG); Balamurugan RAMASAMY, Bangalore (IN)

(21) Appl. No.: 18/372,792

(22) Filed: Sep. 26, 2023

Related U.S. Application Data
(60) Provisional application No. 63/412,360, filed on Sep. 30, 2022.

(51) Int. Cl. C23C 16/505; C23C 16/04; C23C 16/32; C23C 16/56; H01J 37/32

(52) U.S. Cl. CPC C23C 16/505; C23C 16/045; C23C 16/325; C23C 16/56; H01J 37/32165; H01J 37/3244; H01J 2237/3321

(57) ABSTRACT

A method of processing a substrate is disclosed which includes depositing a layer in a processing chamber on a field region, a sidewall region, and a fill region of a feature of the substrate, wherein a hardness of a portion of the layer deposited on the sidewall region is lower than a hardness of a portion of the layer deposited on the field region, and lower than a hardness of a portion of the layer deposited on the fill region.

### CROSS-REFERENCE TO RELATED APPLICATIONS

This application claims benefit of U.S. provisional patent application Ser. No. 63/412,360, filed Sep. 30, 2022, which is herein incorporated by reference.

### FIELD

Embodiments of the present disclosure generally relate to substrate fabrication techniques used, for example, in thin film processing.

### BACKGROUND

The inventors have observed silicon oxide (SiO) layer cracking in the 25 μm SiO inter-die gapfill process flow after grinding and chemical mechanical polishing (CMP). The inventors have studied the stress development mechanisms for the SiO cracking issue due to thermal (coefficient of thermal expansion, or CTE, mismatch) and mechanical (force of grinding and CMP).

Thus, the inventors have provided improved methods of processing substrates to deposit thin films with improved stability, which can be used to reduce or eliminate the inter-die gapfill layer cracking after mechanical processing.

### SUMMARY

Methods for processing substrates and structures formed by such methods are provided herein. In embodiments, a method of processing a substrate comprises depositing a layer in a processing chamber on a field region, a sidewall region, and a fill region of a feature of the substrate, wherein a hardness of a portion of the layer deposited on the sidewall region is lower than a hardness of a portion of the layer deposited on the field region, and lower than a hardness of a portion of the layer deposited on the fill region.

In embodiments, a method of processing a substrate comprises depositing a layer on a field region, a sidewall region, and a fill region of a feature of the substrate, wherein a hardness of a portion of the layer deposited on the sidewall region is lower than a hardness of a portion of the layer deposited on the field region, and lower than a hardness of a portion of the layer deposited on the fill region; and reducing a thickness of at least a portion of the substrate via chemical mechanical planarization to form a processed substrate, wherein the portion of the layer on the sidewall region of the processed substrate is free from cracks.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a schematic diagram of a substrate in accordance with at least some embodiments of the present disclosure.

FIG. 2 is a schematic diagram of a processing chamber in accordance with at least some embodiments of the present disclosure.

FIG. 3 is a flowchart of a method in accordance with at least some embodiments of the present disclosure.

FIG. 4 is a flowchart of a method in accordance with at least some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provided herein can be used, for example, in inter-die gapfill processes to reduce or eliminate cracking of a fill layer during a subsequent planarization process (e.g., grinding and/or CMP and/or the like).

In embodiments, the process for depositing a fill material, which in embodiments is an undoped and/or doped silicon oxide glass material, for die that are bonded to an underlying wafer. The mechanical and thermal properties of the glass gap fill material are controlled by the deposition conditions to survive crack free through post integration processes that may include mechanical stress, e.g. from grinding and/or CMP, and thermal stress, e.g. from anneals and/or subsequent depositions. The bonded die thickness may be from less than about 1 micrometer to 5000 micrometers. The spacing between bonded die may be from about 5 micrometers to 5 centimeters.

To prevent the deposited fill material, e.g., the glass gap fill material, from cracking during post mechanical processing, the glass hardness and Young's modulus are controlled to be locally lowest on the die sidewall. The inventors have discovered that the relatively softer fill material on the die sidewall reduces internal stresses induced from external mechanical shear and load forces during mechanical processes.

In some embodiments, a method for processing a substrate includes controlling a deposition process to deposit a fill layer in a trench such that material deposited in a sidewall region adjacent sidewalls of the trench are softer than material deposited elsewhere within trench and atop the substrate. The method can be performed on a substrate wherein the trench is defined as the region between adjacent sidewalls. The material being deposited can be a fill material deposited atop the substrate and within the trench, for example atop the upper surfaces of the substrate, the sidewalls of the trench, and the bottom of the trench, and can be, for example, one or more of silicon, silicon oxide, silicon nitride, or silicon carbon nitride. In embodiments, the fill material further includes a dopant.

Methods in accordance with the present disclosure selectively modulate the modulus of film deposited on a sidewall of a trench being filled to buffer the stress on the layer during a subsequent mechanical processes such at planarization process (e.g., grinding and/or CMP and/or the like). Methods in accordance with the present disclosure modulate (e.g., lower) the Young's modulus of a deposited film at the sidewall inside a trench structure by control of the chemical vapor deposition (CVD) process used to deposit the film.

The inventors have observed that alternate approaches focusing on optimization of grinding and polishing processes would likely result in slower material removal rates, which would undesirably reduce throughput and increase cost. Methods in accordance with the present disclosure advantageously have little or no cost of ownership impact to the planarization process. In addition, methods in accordance with the present disclosure are more effective in mitigating mechanical film failure and for inter-die gapfill in 3D packaging, amongst other applications.

In embodiments, the method of processing a substrate includes depositing a layer in a processing chamber on a field region, a sidewall region, and a fill region of a feature of the substrate, wherein a hardness of a portion of the layer deposited on the sidewall region is lower than a hardness of a portion of the layer deposited on the field region, and lower than a hardness of a portion of the layer deposited on the fill region. In embodiments, the layer is silicon, silicon oxide, silicon nitride, or silicon carbon nitride. In embodiments, the layer further comprises phosphorus, boron, fluorine, aluminum, nitrogen, or a combination thereof.

In embodiments, the portion of the layer deposited on the sidewall region has a Young's modulus which is at least about 10% lower than a Young's modulus of the portion of the layer deposited on the field region and the portion of the layer deposited on the fill region. In embodiments, the layer is deposited via plasma enhanced chemical vapor deposition (PECVD) or chemical vapor deposition (CVD).

In embodiments, the layer is deposited utilizing a chemical precursor comprising tetraethyl orthosilicate, octamethylcyclotetrasiloxane, silane, or a combination thereof. In embodiments, a flow rate of the chemical precursor into the processing chamber is from about 0.1 to 5 grams/min.

In embodiments, the layer is deposited utilizing a dopant chemical precursor comprising phosphorus, boron, fluorine, aluminum, or a combination thereof. In embodiments, the dopant chemical precursor is provided into the processing chamber at a flow rate from about 0.1 to 2 grams/minute.

In embodiments, the method further comprises diluting the chemical precursor in a carrier gas comprising Ar, He, Hz, or a combination thereof. In embodiments, the carrier gas is provided into the processing chamber at a flow rate from about 1 to 100 slm. In embodiments, the layer is deposited utilizing an oxygen precursor of diatomic oxygen, ozone, nitrous oxide, or a combination thereof, and wherein the oxygen precursor is provided into the processing chamber at a flow rate from about 1 to 50 slm.

In embodiments, the plasma enhanced chemical vapor deposition comprises a dual frequency RF bias comprising a low frequency RF signal having a frequency of about 200 kHz to 600 kHz, and a high frequency RF signal having a frequency of about 2 MHz to 100 MHz.

In embodiments, a power of the low frequency RF signal and a power of the high frequency RF signal are each individually from about 50 watts to about 5000 watts. In embodiments, a ratio of a power of the low frequency RF signal to a power of the high frequency RF signal is greater than 1. In embodiments, wherein one of the high frequency RF signal or the low frequency RF signal is applied to a showerhead configured to flow gases into the processing chamber, and the other is applied to a substrate support configured to support the substrate during the processing.

In embodiments, a spacing between a showerhead of the processing chamber and the substrate support is from about 50 mils to 1500 mils. In embodiments, a temperature of the substrate is from about 50° C. to about 500° C. In embodiments, a pressure within the processing chamber is from about 0.1 torr to about 10 torr.

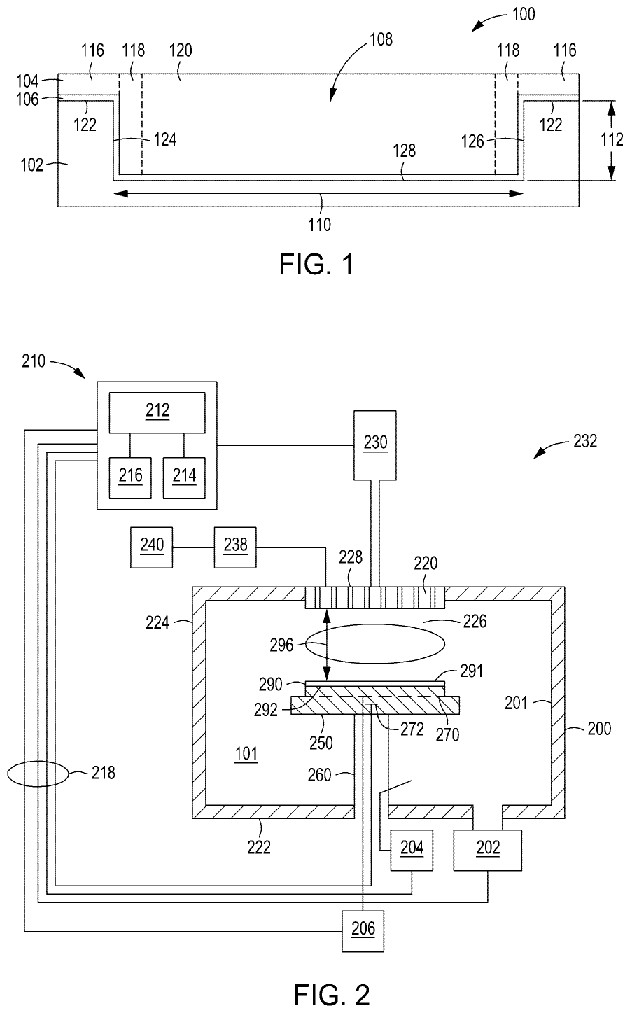

FIG. 1 is a schematic diagram of a packaging structure 100 in accordance with at least some embodiments of the present disclosure. Although described herein in connection with packaging applications, embodiments of the present disclosure can be advantageously used in other thin film fabrication applications where materials are deposited in trenches and subsequently subject to grinding and/or polishing and risk of developing cracks. Although described herein using a packaging structure for illustration, the inventive methods disclosed herein can be used in other applications where features such as trenches are filled on a substrate.

The packaging structure 100 generally includes a substrate 102 including a plurality of fields 122 e.g., upper surfaces of the substrate 102 and a trench 108 disposed between adjacent sidewalls 124 and 126. The trench 108 can have any suitable dimensions for a particular application such as, for example, a width 110 of about 80 micrometers and a depth 112 of about 20-30 micrometers. The bottom of the trench forms the bottom region 128.

In some embodiments, an optional barrier and/or liner layer 106 may be conformally disposed atop the substrate 102. For example, across a top or fields 122 of the silicon layer, along the sidewalls 124 and 126 and along the bottom region 128 of the trench 108. In some embodiments, the barrier and/or liner layer 106 can be a silicon nitride layer.

A fill layer 104 is disposed atop the substrate 102 (e.g., over the fields 122, the sidewalls 124 and 126, and the bottom region 128) and, when present the barrier and/or liner layer 106. The fill layer 104 can be silicon, silicon oxide, silicon nitride, silicon carbon nitride, or combinations thereof. In some embodiments, the fill layer consists of or consists essentially of one of silicon, silicon oxide, silicon nitride, or silicon carbon nitride. The fill layer 104 includes a field region 116, generally disposed atop the fields 122 of the substrate 102 (e.g., upper surfaces of the feature disposed into the substrate 102), a sidewall region 118 disposed along and proximate the sidewalls 124 and 126 of the trench 108 and/or the barrier and/or liner layer 106 when present, and a fill region 120 disposed within the trench 108 (e.g., atop the bottom region 128 of the trench 108 and between the sidewall regions 118) and generally filling the trench 108. The fill layer 104 is typically deposited to a thickness such that an upper surface of the fill layer 104 is disposed above the fields 122 i.e., the upper surface of the substrate 102, and when present, the barrier and/or liner layer 106. In some embodiments, depending on the trench 108 structure and critical dimension (e.g., the width of the trench 108), the sidewall region 118 can have a width or thickness (e.g., measured from the wall of the trench 108 inward to an opposing side of the sidewall region 118) of about 5 nanometers to about 50 micrometers.

In processes currently known in the art, the harness of all the various layers are essentially identical. In processes according to the instant disclosure, the field region 116 and the fill region 120 have a first hardness (e.g., as represented by the Young's modulus of the film) that is greater than a second hardness of the sidewall region 118. In some embodiments, the first hardness, or Young's modulus, is a nominal value typical of the as-deposited film. The second hardness is less than the first hardness. In some embodiments, the Young's modulus of the sidewall region 118 is about 10-15% lower than the Young's modulus of the field region 116 and the fill region 120 (e.g., taking average readings). In embodiments, the portion of the layer deposited on the sidewall region has a Young's modulus which is at least about 10% lower than a Young's modulus of the portion of the layer deposited on the field region and the portion of the layer deposited on the fill region.

For example, where the fill layer 104 is a silicon oxide layer, the Young's modulus of the field region 116 and the fill region 120 can be about 85 GPa, and the Young's modulus of the sidewall region 118 can be about 75 GPa. Other values can be obtained with silicon oxide layers, or when the fill layer 104 is fabricated from different materials as noted above. For example, in some embodiments, the Young's modulus of a silicon oxide layer can vary between about 59-85 GPa. In some embodiments, the Young's modulus of a silicon nitride layer can vary between about 200-280 GPa. In some embodiments, the Young's modulus of a silicon layer can vary between about 67-80 GPa.

Methods in accordance with the present disclosure modulate (e.g., lower) the Young's modulus of a deposited film (e.g., fill layer 104) at the sidewall inside a trench structure by control of a CVD process used to deposit the film. For example, the inventors have discovered that control of the process parameters of the CVD process can be used to control the hardness of the deposited film. For example, control of a high frequency to low frequency RF ratio, control of chamber pressure, control of gas and precursor flow, and/or control of substrate-to-showerhead spacing can be used single or in combinations of two or more to control the hardness of the deposited film along the sidewall region as compared to the other regions of the fill layer.

In embodiments, multiple mixed RF frequencies may be used to create the plasma for deposition including a high frequency from about 2-100 MHz, and a low frequency from about 200-600 kHz. In some embodiments, a plurality of high frequencies from 2-100 MHz and/or a plurality of low frequencies from 200-600 KHz may be used.

In embodiments, each of the power of the high frequency RF and the power of the low frequency RF are independently controlled. In embodiments, the power of each RF frequency is provided continuously or pulsed for each RF frequency during deposition. In embodiments, the power of the low frequency RF and the power of the high frequency RF is in a range from about 50 to 5000 W.

In embodiments, using PECVD, the deposited silicon oxide fill material hardness and modulus on die sidewall may be reduced by increasing the ratio of a low frequency RF power to high frequency RF power to greater than or equal to about 1, or greater than or equal to about 1.2, or greater than or equal to about 1.5, or greater than or equal to about 2, wherein each of the low RF power and the high RF power are from about 50 to 5000 watts.

In embodiments, the gap fill material is deposited using plasma enhanced chemical vapor deposition chamber (PECVD) with a capacitive coupled plasma (CCP) hardware configuration.

In embodiments, the layer is deposited by plasma enhanced chemical vapor deposition (PECVD), or by chemical vapor deposition (CVD). In embodiments, the chemical vapor deposition utilizes a chemical precursor comprising tetraethyl orthosilicate (TEOS), octamethylcyclotetrasiloxane (OMCTS), and/or SiH₄, with flow rates from about 0.1 to 5 grams/minute. In embodiments, an oxygen precursor is utilized, which may include O₂, O₃, and/or N₂O, with flow rates from about 1 to 50 slm.

In embodiments, a method of processing a substrate comprises depositing a layer in a processing chamber on a field region, a sidewall region, and a fill region of a feature of the substrate, wherein a hardness of a portion of the layer deposited on the sidewall region is lower than a hardness of a portion of the layer deposited on the field region, and lower than a hardness of a portion of the layer deposited on the fill region.

In embodiments, the layer comprises silicon. In embodiments, the layer is silicon, silicon oxide, silicon nitride, or silicon carbon nitride. In embodiments, the layer further comprises a dopant. In embodiments, the dopant comprises phosphorus, boron, fluorine, or a combination thereof. In embodiments, the dopant is present in an amount sufficient to modify a hardness of the layer, such that a portion of the portion of the layer deposited on the sidewall region is lower than a hardness of a portion of the layer deposited on the field region, and lower than a hardness of a portion of the layer deposited on the fill region.

In embodiments, the chemical vapor deposition utilizes a chemical precursor comprising a dopant. In embodiments, the dopant comprises an element from one or more of Groups 1-2 and/or 11-15 of the periodic table of the elements. In embodiments, the dopant comprises phosphorus, boron, aluminum, gallium, indium, silver, arsenic, antimony, bismuth, germanium, gold, platinum, cadmium, or a combination thereof.

In embodiments, the chemical precursor may comprise phosphorus as a dopant, and may comprise at least one of triethylphosphate (TEPO), phosphoryl chloride (e.g., phosphorus oxychloride. POCl₃), phosphine (PH₃), or tertiary butyl phosphine (TBP), and/or the like. In embodiments, the chemical precursor may comprise boron as a dopant, and may comprise at least one of triethylborane (TEB), diborane (B₂H₆), boric acid (H₃BO₃), or the like. In embodiments, the chemical precursor may comprise aluminum as a dopant, and may comprise at least one of trimethylaluminum (TMA), triethylaluminum (TEA), ammonia, nitrogen, or the like. In embodiments, the chemical precursor may comprise gallium as a dopant, and may comprise at least one of trimethylgallium (TMG), triethylgallium (TEG), gallium arsenide, gallium phosphide, gallium nitride, indium gallium nitride, aluminum gallium nitride, and/or the like. In embodiments, the chemical precursor may comprise both silver and phosphorus as a dopant, and may comprise silver phosphine precursors.

In embodiments, the dopant is provided at a flow rate from about 0.1 to 2 grams/minute, and may be diluted in a carrier gases such as Ar, He, Hz, or the like, wherein the diluent is provided at a flow rate from about 1 to 100 slm.

In embodiments, the dopant concentration is present in the precursor in an amount sufficient to produce a final layer having a dopant concentration from about 1-30 atomic %, or from about 1-10 atomic %, or from about 3-7 atomic %.

In embodiments, the layers are deposited as composite layers. For example, a first deposit comprising a doped liner may be deposited followed by an undoped deposition to finish the gapfill. Deposition of any number of such layers in any order is contemplated.

FIG. 2 is a schematic representation of a substrate processing chamber 200, which can be used for processing substrates according to embodiments described herein. However, the processes described herein may be performed on other substrate processing chambers as well.

The processing chamber 200 is coupled to a gas panel 230 and a controller 210. The processing chamber 200 generally includes a top 224, a side 201 and a bottom wall 222 that define an interior processing volume 226. A substrate support 250 is provided in the interior processing volume 226 of the processing chamber 200. The substrate support 250 is supported by a stem 260 and may be typically fabricated from aluminum, ceramic, and other suitable materials. The substrate support 250 may be moved in a vertical direction inside the processing chamber 200 using a displacement mechanism to a control a distance 223 between the substrate 291 and the showerhead 220.

In embodiments, the substrate support 250 for the substrate 290 e.g., a wafer) and a showerhead 220 for gas/precursor distribution are utilized as the anode/cathode for RF delivery and plasma generation. In embodiments, a spacing 296 between the substrate 290 and the showerhead 220 during plasma deposition may be from about 50 mils to 1500 mils.

The substrate support 250 may include an embedded heater element 270 suitable for controlling the temperature of a substrate 290 supported on a surface 292 of the substrate support 250. The substrate support 250 may be resistively heated by applying an electric current from a power supply 206 to the heater element 270. The heater element 270 may be made of a nickel-chromium wire encapsulated in a nickel-iron-chromium alloy (e.g., INCOLOY®) sheath tube. The electric current supplied from the power supply 206 is regulated by the controller 210 to control the heat generated by the heater element 270, thereby maintaining the substrate 290 and the substrate support 250 at a substantially constant temperature during film deposition.

A temperature sensor 272, such as a thermocouple, may be embedded in, or otherwise operatively coupled to, the substrate support 250 to measure the temperature of the substrate support 250. The measured temperature is used by the controller 210 to control the power supplied to the heater element 270 to maintain the substrate at a desired temperature.

In embodiments, the substrate 290 temperature is from about 50° C. to 500° C., or from about 200° C. to 350° C. during deposition. In embodiments, the substrate support 250 is configured for wafer chucking to keep the wafer flat and in close contact to the heater 270 during deposition, and the heater 270 has precise temperature control capability, i.e. +/−1C during the entire deposition processing to enable accurate control and uniformity of the deposited film properties across the wafer. In embodiments, the pressure within the interior processing volume 226 is from about 0.1-10 torr during the deposition.

A vacuum pump 202 is coupled to a port formed in the bottom of the processing chamber 200. The vacuum pump 202 is used to maintain a desired gas pressure in the processing chamber 200. The vacuum pump 202 also evacuates post-processing gases and by-products of the process from the processing chamber 200.

The substrate processing chamber 200 may further include additional equipment for controlling the chamber pressure, for example, valves (e.g., throttle valves and isolation valves) positioned between the processing chamber 200 and the vacuum pump 202 to control the chamber pressure.

A showerhead 220 having a plurality of apertures 228 is disposed on the top of the processing chamber 200 above the substrate support 250. The apertures 228 of the showerhead 220 are utilized to introduce process gases into the processing chamber 200. The apertures 228 may have different sizes, number, distributions, shape, design, and diameters to facilitate the flow of the various process gases for different process requirements. The showerhead 220 is connected to the gas panel 230 that allows various gases to supply to the interior processing volume 226 during the deposition process.

The gas panel 230 may also be used to control and supply various chemical vapor deposition precursors and/or reagents, which may be either in gaseous, or may be in liquid form, which are vaporized and delivered to the processing chamber 200 in the presence of a carrier gas. The carrier gas is typically an inert gas, such as nitrogen, or a noble gas, such as argon or helium. Alternatively, the liquid precursor may be vaporized from an ampoule by a thermal and/or vacuum enhanced vaporization process.

The showerhead 220 and substrate support 250 may form a pair of spaced apart electrodes in the interior processing volume 226. One or more RF power sources 240 and 241 provide a bias potential through a corresponding matching network 238 and 239 to the showerhead 220, to the substrate support, or a combination thereof, to facilitate the chemical vapor deposition between the showerhead 220 and the substrate support 250. The RF power sources 240 and matching network 238 may be coupled to the showerhead 220, substrate support 250, or coupled to both the showerhead 220 and the substrate support 250. In one embodiment, the RF power sources 240 and 241 include a low frequency RF power source and a high frequency power source. Each RF power source may provide between about 50 Watts and about 5,000 Watts of power.

The controller 210 includes a central processing unit (CPU) 212, a memory 216, and a support circuit 214 utilized to control the process sequence and regulate the gas flows from the gas panel 230. The CPU 212 may be of any form of a general purpose computer processor that may be used in an industrial setting. The software routines can be stored in the memory 216, such as random access memory, read only memory, floppy, or hard disk drive, or other form of digital storage. The support circuit 214 is conventionally coupled to the CPU 212 and may include cache, clock circuits, input/output systems, power supplies, and the like. Bi-directional communications between the controller 210 and the various components of the substrate processing chamber 232 are handled through numerous signal cables collectively referred to as signal buses 218, some of which are illustrated in FIG. 2.

In embodiments, a spacing 296 between a showerhead 220 of the processing chamber 200 and the substrate support 250 is less than a comparative spacing between the showerhead of the processing chamber and the substrate support which is sufficient to deposit a comparative layer on a field region, a sidewall region, and a fill region of the feature of the substrate under otherwise essentially identical conditions, except that a hardness of the portion of the comparative layer deposited on the sidewall region, a hardness of the portion of the comparative layer deposited on the field region, and a hardness of the portion of the comparative layer deposited on the fill region are essentially equal.

In embodiments, a spacing 296 between a showerhead of the processing chamber 200 and the substrate support 250 is greater than a spacing between the showerhead of the processing chamber and the substrate support which is sufficient to deposit a comparative layer on a field region, a sidewall region, and a fill region of the feature of the substrate under otherwise essentially identical conditions, except that a hardness of the portion of the comparative layer deposited on the sidewall region, a hardness of the portion of the comparative layer deposited on the field region, and a hardness of the portion of the comparative layer deposited on the fill region are essentially equal.

In embodiments, a spacing between a showerhead of the processing chamber and the substrate support is from about 1 to about 20 cm.

In embodiments, the CVD process can be performed in a processing chamber having dual frequency RF bias of the showerhead that flows gases into the processing chamber during processing. The dual frequency RF bias can include a low frequency (LF) RF signal and a high frequency (HF) RF signal.

Other chamber configurations are also possible, for example, where the HF and LF power are both applied to a substrate support that supports the substrate during processing, or wherein one of the HF or LF power is applied to the showerhead and the other is coupled to the substrate support. In some embodiments, the low frequency can be about 200 kHz to 600 kHz. In some embodiments, the high frequency can be about 2 MHz to 100 MHz

The inventors have discovered that depositing the fill layer 104 using a CVD process wherein the HF power applied is greater than the LF power applied results in a film having a nominal hardness or Young's modulus. However, reducing the HF closer to the LF or lower than the LF is effective to deposit softer films at the sidewall.

In embodiments, a power of the high frequency RF signal is about 50% to about 105% of a power of the low frequency RF signal.

In embodiments, both the high frequency RF signal and the low frequency RF signal are applied to a showerhead configured to flow gases into the processing chamber or to a substrate support configured to support the substrate during the processing.

In embodiments, one of the high frequency RF signal or the low frequency RF signal is applied to a showerhead configured to flow gases into the processing chamber, and the other is applied to a substrate support configured to support the substrate during the processing. For example, in one embodiment, the high frequency RF signal is applied to a showerhead configured to flow gases into the processing chamber, and the low frequency RF signal is applied to a substrate support configured to support the substrate during the processing. In one embodiment, the low frequency RF signal is applied to a showerhead configured to flow gases into the processing chamber, and the high frequency RF signal is applied to a substrate support configured to support the substrate during the processing.

For example, the inventors have discovered that higher precursor flow (such as TEOS) and/or lower O₂ or N₂O flow tends to lead to deposition of softer films. In embodiments, the chemical precursor is mixed with a diluent. Suitable diluents include argon, helium, neon, nitrogen, and the like.

In embodiments, a flow rate of a chemical precursor is greater than a flow rate of the same chemical precursor which is sufficient to deposit a comparative layer on a field region, a sidewall region, and a fill region of the feature of the substrate under otherwise essentially identical conditions, except that a hardness of the portion of the comparative layer deposited on the sidewall region, a hardness of the portion of the comparative layer deposited on the field region, and a hardness of the portion of the comparative layer deposited on the fill region are essentially equal.

In embodiments, a flow rate of oxygen, nitrous oxide, or a combination thereof, is less than a flow rate of the same which is sufficient to deposit a comparative layer on a field region, a sidewall region, and a fill region of the feature of the substrate under otherwise essentially identical conditions, except that a hardness of the portion of the comparative layer deposited on the sidewall region, a hardness of the portion of the comparative layer deposited on the field region, and a hardness of the portion of the comparative layer deposited on the fill region are essentially equal.

In embodiments, a flow rate of oxygen, nitrous oxide, or a combination thereof, is less than a flow rate of the same which is sufficient to deposit a comparative layer on a field region, a sidewall region, and a fill region of the feature of the substrate under otherwise essentially identical conditions, except that a hardness of the portion of the comparative layer deposited on the sidewall region, a hardness of the portion of the comparative layer deposited on the field region, and a hardness of the portion of the comparative layer deposited on the fill region are essentially equal.

In embodiments, a deposition pressure within the processing chamber is greater than a deposition pressure of the processing chamber which is sufficient to deposit a comparative layer on a field region, a sidewall region, and a fill region of the feature of the substrate under otherwise essentially identical conditions, except that a hardness of the portion of the comparative layer deposited on the sidewall region, a hardness of the portion of the comparative layer deposited on the field region, and a hardness of the portion of the comparative layer deposited on the fill region are essentially equal.

In embodiments, a deposition pressure within the processing chamber is lower than a deposition pressure of the processing chamber which is sufficient to deposit a comparative layer on a field region, a sidewall region, and a fill region of the feature of the substrate under otherwise essentially identical conditions, except that a hardness of the portion of the comparative layer deposited on the sidewall region, a hardness of the portion of the comparative layer deposited on the field region, and a hardness of the portion of the comparative layer deposited on the fill region are essentially equal.

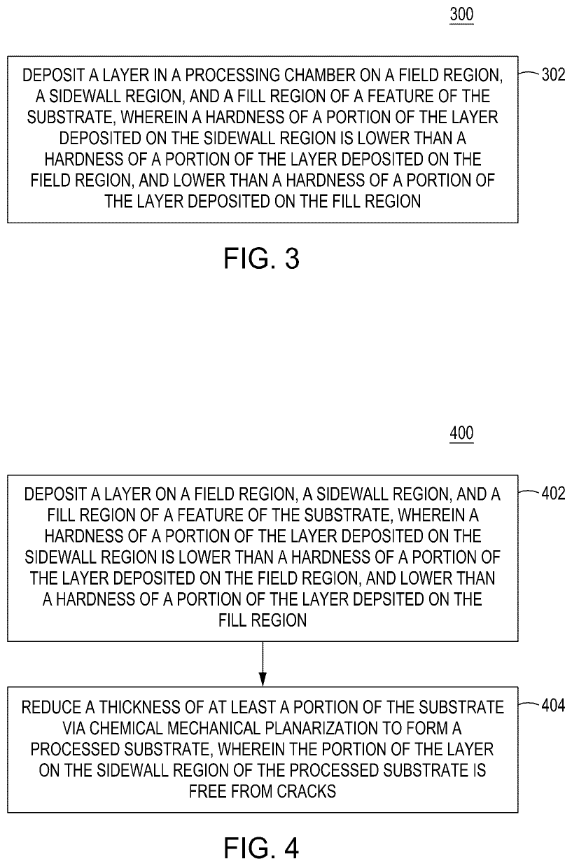

FIG. 3 is a flowchart of an example process 300. In some embodiments, block 302 of FIG. 3 may be performed by a device.

As shown in FIG. 3, process 300 may include depositing a layer in a processing chamber on a field region, a sidewall region, and a fill region of a feature of the substrate, where a hardness of a portion of the layer deposited on the sidewall region is lower than a hardness of a portion of the layer deposited on the field region, and lower than a hardness of a portion of the layer deposited on the fill region (block 302). Although FIG. 3 shows an example block of process 300, in some implementations, process 300 may include additional blocks.

FIG. 4 is a flowchart of an example process 400. In some embodiments, one or more blocks of FIG. 4 may be performed by a device.

As shown in FIG. 4, process 400 may include depositing a layer on a field region, a sidewall region, and a fill region of a feature of the substrate, where a hardness of a portion of the layer deposited on the sidewall region is lower than a hardness of a portion of the layer deposited on the field region, and lower than a hardness of a portion of the layer deposited on the fill region (block 402). As also shown in FIG. 4, process 400 may include reducing a thickness of at least a portion of the substrate via chemical mechanical planarization to form a processed substrate, where the portion of the layer on the sidewall region of the processed substrate is free from cracks (block 404). Although FIG. 4 shows example blocks of process 400, in some implementations, process 400 may include additional blocks.

While the foregoing is directed to embodiments of the present disclosure, other and further embodiments of the disclosure may be devised without departing from the basic scope thereof.

1. A method of processing a substrate, comprising:
depositing a layer in a processing chamber on a field region, a sidewall region, and a fill region of a feature of the substrate, wherein a hardness of a portion of the layer deposited on the sidewall region is lower than a hardness of a portion of the layer deposited on the field region, and lower than a hardness of a portion of the layer deposited on the fill region.

2. The method of claim 1, wherein the layer is silicon, silicon oxide, silicon nitride, or silicon carbon nitride.

3. The method of claim 1, wherein the layer further comprises phosphorus, boron, fluorine, aluminum, nitrogen, or a combination thereof.

4. The method of claim 1, wherein the portion of the layer deposited on the sidewall region has a Young's modulus which is at least about 10% lower than a Young's modulus of the portion of the layer deposited on the field region and the portion of the layer deposited on the fill region.

5. The method of claim 1, wherein the layer is deposited via plasma enhanced chemical vapor deposition (PECVD) or chemical vapor deposition (CVD).

6. The method of claim 5, wherein the layer is deposited utilizing a chemical precursor comprising tetraethyl orthosilicate, octamethylcyclotetrasiloxane, silane, or a combination thereof.

7. The method of claim 6, wherein a flow rate of the chemical precursor into the processing chamber is from about 0.1 to 5 grams/min.

8. The method of claim 6, wherein the layer is deposited utilizing a dopant chemical precursor comprising phosphorus, boron, fluorine, aluminum, or a combination thereof.

9. The method of claim 8, wherein the dopant chemical precursor is provided into the processing chamber at a flow rate from about 0.1 to 2 grams/minute.

10. The method of claim 6, further comprising diluting the chemical precursor in a carrier gas comprising Ar, He, Hz, or a combination thereof.

11. The method of claim 10, wherein the carrier gas is provided into the processing chamber at a flow rate from about 1 to 100 slm.

12. The method of claim 6, wherein the layer is deposited utilizing an oxygen precursor of diatomic oxygen, ozone, nitrous oxide, or a combination thereof, and wherein the oxygen precursor is provided into the processing chamber at a flow rate from about 1 to 50 slm.

13. The method of claim 5, wherein the plasma enhanced chemical vapor deposition comprises a dual frequency RF bias comprising a low frequency RF signal having a frequency of about 200 kHz to 600 kHz, and a high frequency RF signal having a frequency of about 2 MHz to 100 MHz.

14. The method of claim 13, wherein a power of the low frequency RF signal and a power of the high frequency RF signal are each individually from about 50 watts to about 5000 watts.

15. The method of claim 13, wherein a ratio of a power of the low frequency RF signal to a power of the high frequency RF signal is greater than 1.

16. The method of claim 13, wherein one of the high frequency RF signal or the low frequency RF signal is applied to a showerhead configured to flow gases into the processing chamber, and the other is applied to a substrate support configured to support the substrate during the processing.

17. The method of claim 16, wherein a spacing between a showerhead of the processing chamber and the substrate support is from about 50 mils to 1500 mils.

18. The method of claim 1, wherein a temperature of the substrate is from about 50° C. to about 500° C.

19. The method of claim 1, wherein a pressure within the processing chamber is from about 0.1 torr to about 10 torr.

20. A method of processing a substrate, comprising:
depositing a layer on a field region, a sidewall region, and a fill region of a feature of the substrate, wherein a hardness of a portion of the layer deposited on the sidewall region is lower than a hardness of a portion of the layer deposited on the field region, and lower than a hardness of a portion of the layer deposited on the fill region; and
reducing a thickness of at least a portion of the substrate via chemical mechanical planarization to form a processed substrate, wherein the portion of the layer on the sidewall region of the processed substrate is free from cracks.
